(19) United States
(12) Patent Application Publication
(10) Pub. No.: US 2008/0099802 A1
(43) Pub. Date: May 1, 2008

(54) Transmission line transistor

(76) Inventor: Michael Vice, El Granada, CA (US)

Correspondence Address: Kathy Manke;Avago Technologies Limited, 4380 Ziegler Road, Fort Collins, CO, 80525, US

(21) Appl. No.: 11/585,265

(22) Filed: Oct. 24, 2006

(51) Int. Cl. H01L 29/76

(52) U.S. Cl. 257/288

(57) ABSTRACT

A transistor comprises a gate, a source, and a drain. The gate is configured as a gate transmission line having a first characteristic impedance, and has an input at a first end thereof, and an output at a second end thereof. The source is configured as a source transmission line having a second characteristic impedance, and has an input at a first end thereof, and an output at a second end thereof. The drain is configured as a drain transmission line having a third characteristic impedance, and has an input at a first end thereof, and an output at a second end thereof.

### BACKGROUND

As transistor circuits are called upon to operate into the microwave and millimeter wave frequency ranges over broader bandwidths, the lumped capacitance of the transistors becomes increasingly difficult to tolerate. At frequencies below a few gigahertz the capacitance can be neglected by selecting a process and transistor design that produces a sufficiently small capacitance. Alternatively, when only a narrow bandwidth is required, then the capacitance can be absorbed into a reactive matching network. However, in transistors operating across multi-octave bandwidths above a few gigahertz, then neither of the preceding solutions is very effective.

To address this problem, the distributed amplifier was developed. A distributed amplifier is realized by dividing the transistor periphery into an array of smaller devices separated by inductors. These inductors are often realized by narrow width (high impedance) transmission lines. The transmission lines and transistors are arranged in a ladder configuration that forms a synthetic transmission line. The result is a system that advantageously absorbs the transistor capacitance into a broadband transmission line-like structure that can efficiently handle the necessary frequency range. Since a synthetic transmission line can operate from frequencies of 0 Hz up to some very high cutoff frequency, systems designed around the distributed amplifier approach can achieve virtually an infinite amount of octave bandwidth.

In passive applications such as switches and attenuators, the distributed approach shows up again as a preferred way to achieve broad bandwidths at high frequencies in the presence of significant transistor capacitance. The distributed topologies appear in such circuits where shunt transistors are needed, and they take the form of series high impedance line segments separated by shunt transistors.

However, a principle weakness of the distributed amplifier approach relates to the synthetic transmission line itself. There is always a residual passband ripple, the amplitude of which is determined by the upper cutoff frequency and the number of sections in the synthetic transmission line. That is, the passband ripple can be improved, but doing so requires the addition of more sections to the synthetic transmission line. However, the number of sections is limited by the space available for laying out the circuit. Accordingly, a compromise is forced between bandwidth, ripple, and layout size, and the results are not always satisfactory.

What is needed, therefore, is a transistor that can provide wideband, high frequency performance without significant passband ripple. What is also needed is a transistor with wideband, high frequency performance capabilities that can be fabricated with a smaller size.

### SUMMARY

In an example embodiment, a transistor comprises a gate, a source, and a drain. The gate is configured as a gate transmission line having a first characteristic impedance at a particular bias condition. The gate has an input at a first end thereof, and an output at a second end thereof. The source is configured as a source transmission line having a second characteristic impedance at the particular bias condition. The source has an input at a first end thereof, and an output at a second end thereof. The drain is configured as a drain transmission line having a third characteristic impedance at the particular bias condition. The drain has an input at a first end thereof, and an output at a second end thereof.

In another example embodiment, a method of providing a transistor comprises selecting a first characteristic impedance for a gate transmission line; providing a gate configured as the gate transmission line having the first characteristic impedance at a particular bias condition, the gate having an input at a first end thereof, and an output at a second end thereof; selecting a second characteristic impedance for a source transmission line; providing a source configured as the source transmission line having the second characteristic impedance at the particular bias condition, the source having an input at a first end thereof, and an output at a second end thereof; selecting a third characteristic impedance for a drain transmission line; and providing a drain configured as the drain transmission line having the third characteristic impedance at the particular bias condition, the drain having an input at a first end thereof, and an output at a second end thereof.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 shows a schematic diagram of one embodiment of a transmission line transistor;

FIG. 2 shows a schematic diagram of another embodiment of a transmission line transistor.

FIG. 3 shows a schematic diagram of a transistor with a single gate port terminal and a single drain port terminal.

FIG. 4 shows a schematic diagram of a transmission line transistor with separate input and output port terminals for the gate and the drain.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

In the description to follow, when it is said that two or more components or points are connected to each other, it should be understood that does not preclude the possibility of the existence of intervening elements or components. In contrast, when it is said that two or more components or points are directly connected to each other, it should be understood that the two components or points are connected without any intervening components or circuits that significantly affect a signal passed across the connection. However a conductive contact, wire, or line which does not present substantial capacitance, inductance, or resistance at frequencies of interest may be used to directly connect the two or more components or points. Also, as used herein, a “line” means something that is distinct, elongated, and relatively narrow. It can be curved, straight, or bent unless otherwise indicated. It is not to be construed in a strict mathematical sense as having no width, or as being generated by a moving point, unless otherwise specifically indicated.

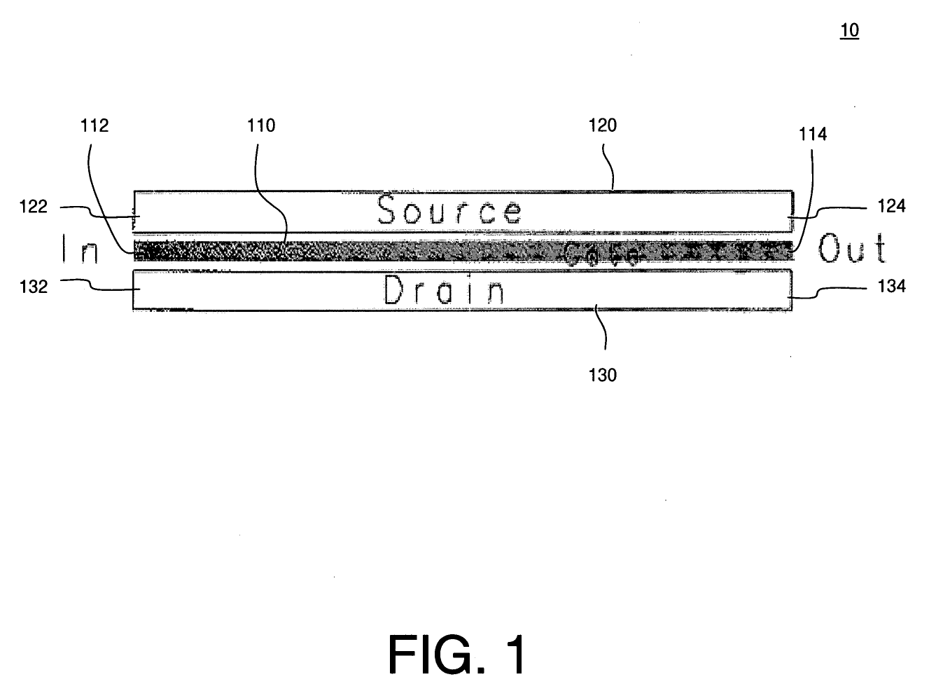

FIG. 1 shows a schematic diagram of one embodiment of a transmission line transistor 10 having a gate 110, a source 120, and a drain 130. Transmission line transistor 10 is a field effect transistor (FET). In transmission line transistor 10, gate 110, source 120, and drain 130 each have the geometry of a single finger trace. The finger traces of gate 110, source 120, and drain 130 are each configured to operate as transmission lines at operating frequencies of transmission line transistor 10. That is, the finger trace of gate 110 is configured as a gate transmission line having a first characteristic impedance, the finger trace of source 120 is configured as a source transmission line having a second characteristic impedance, and the finger trace of drain 130 is configured as a drain transmission line having a third characteristic impedance. Beneficially, the values of one or all of the first, second, and third characteristic impedances are selected in view of external circuitry to which transmission line transistor 10 is connected, or is expected to be connected. For example, in some cases one or more of the characteristic impedances may be selected to match an output impedance of a circuit supplying an input signal to transmission line transistor 10, or an input impedance of a circuit receiving an output signal from transmission line transistor 10.

It should be appreciated that the characteristic impedance of each transmission line is interactive with that of each of the other transmission lines. For instance, the characteristic impedance of the gate transmission line is dependent on the geometry of the drain and source transmission lines. Additionally, each transmission line impedance is affected by the load impedances attached to the terminals of the remaining transmission lines. For these reasons, the transmission line impedances are normally determined concurrently with each other and with consideration to the external load impedances that are expected to appear at each terminal of each transmission line of the transistor, as provided by the surrounding application circuit in which the transistor is embedded. In general, the impedances in a multiple trace system are complicated. For instance, suppose we have a system of three traces, named trace 1, trace 2, and trace 3. Trace 1 has several impedances: Zₒ(11) is the self impedance of trace 1 with respect to a global ground plane or node. Zₒ(12) is the impedance of trace 1 with respect to trace 2. Zₒ(13) is the impedance of trace 1 with respect to trace 3. The effective characteristic impedance of trace 1 is dependent on each of the impedances defined above, in conjunction with the termination impedances on trace 2 and trace 3 at each end of each trace, as defined by the application circuit.

Gate 110 has an input at a first end 112 of its finger trace, and an output at a second end 114 of its finger trace. Source 120 has an input at a first end 122 of its finger trace, and an output at a second end 124 of its finger trace. Drain 130 has an input 132 at a first end 132 of its finger trace, and an output at a second end 134 of its finger trace. The input of each transmission line denotes the end of the transmission line at which energy is launched into the transmission line from a source and the end of the transmission line from which energy traveling in a reverse direction as a result of an unwanted reflection is terminated into a load. The output of each transmission line denotes the end of the transmission line at which energy flows from the transmission line into a load. It is seen that, in general, transmission line transistor 10 is a six-terminal device.

Transmission line transistor 10 can be fabricated in a semiconductor substrate such as silicon, germanium, etc., or as a thin film transistor on a generic substrate, such as glass, polymer, etc.

According to this arrangement, as illustrated in FIG. 1, the capacitance of transmission line transistor 10 is continuously distributed along the gate, source, and drain transmission lines. As a result, the bandwidth of transmission line transistor 10 can be made extremely large, and the ripple can be made virtually nonexistent when the impedances of the transmission lines are properly selected.

In order for transmission line transistor 10 to operate as a transmission line transistor, the geometric widths of each finger trace must be properly selected to produce the desired characteristic impedance, Z_{O}, according to Equation (1):

Z_{O}=(L/C)^{1/2} (1)

where L and C are the inductance and capacitance, respectively, per unit length of the finger trace. To achieve the desired characteristic impedance for gate 110, source 120, and drain 130, the widths of the finger traces must be carefully selected. A variety of methods are available to accomplish this, including electromagnetic (E/M) field solvers, analytical methods, and empirical methods. For example, in one particular p-High Electron Mobility Transistor (p-HEMT) technology, a characteristic impedance of 50 ohms was achieved with a finger trace having a width of 10 μm.

It should be understood that a specific impedance is only achievable under a specific bias condition for the transistor. Often, the bias condition of interest is at the pinch-off voltage, V_{P}.

In a typical application, the transmission line transistor is configured in a circuit as a shunt transistor. In this case, the source is grounded, and the gate and drain are each configured to operate as transmission lines having desired characteristic impedances.

In many applications, it will be desired that the first, second, and third characteristic impedances are all the same as each other. In particular, in many cases the transmission line transistor will be operated in a circuit with a system impedance of 50 ohms. In that case, it may be desired that first, second, and third characteristic impedances are each 50 ohms.

However, in other cases the first, second, and third characteristic impedances will not be the same as each other. In particular, in some cases it might not be possible to fabricate the gate transmission line with a desired characteristic impedance due to limitations of the fabrication technology. In that case, in particular the first characteristic impedance of the gate transmission line will be different from the third characteristic impedance of the drain transmission line.

The geometric lengths of the finger traces are adjusted to yield a required total periphery. When the finger trace length becomes impractical, then it can be shortened by adding additional parallel finger traces to the transistor.

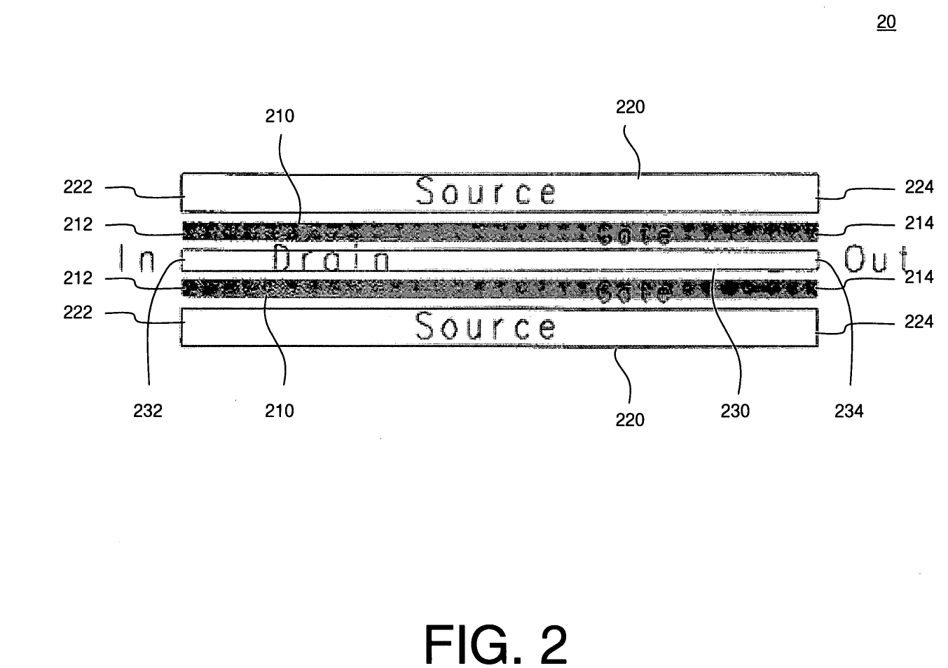

FIG. 2 shows a schematic diagram of another embodiment of a transmission line transistor 20 having two finger traces. In the embodiment of FIG. 2, transmission line transistor 20 is a two-finger FET, having a split gate 210, a split source 220, and a drain 230. The finger traces of gate 210 are configured as a gate transmission line having a first characteristic impedance, the finger traces of source 220 are configured as a source transmission line having a second characteristic impedance, and the finger trace of drain 230 is configured as a drain transmission line having a third characteristic impedance. Gate 210 has an input at a first end 212 of its finger traces, and an output at a second end 214 of its finger traces. Source 220 has an input at a first end 222 of its finger traces, and an output at a second end 224 of its finger traces. Drain 230 has an input at a first end 232 of its finger trace, and an output at a second end 234 of its finger trace. As before, the input of each transmission line denotes the end of the transmission line at which energy is launched into the transmission line from a source and the end of the transmission line from which energy traveling in a reverse direction as a result of an unwanted reflection is terminated into a load. The output of each transmission line denotes the end of the transmission line at which energy flows from the transmission line into a load.

When additional finger traces are added to the transmission line transistor it becomes necessary to adjust the width of each finger trace so that the aggregate of all of the finger traces produces the desired characteristic impedance.

Although FIG. 2 shows an example embodiment of a transmission line transistor having two finger traces, it should be understood that more than two finger traces can be employed instead. However, in general there is a practical limit to the number of finger traces that can be employed while maintaining a desired characteristic impedance, due to the constraints on the minimum width for a finger trace set by limitations of the fabrication technology. The maximum number of finger traces that can be employed is ultimately set by the fabrication technology itself. For example, with less capacitance per unit length, one could select more finger traces for the same resultant characteristic impedance.

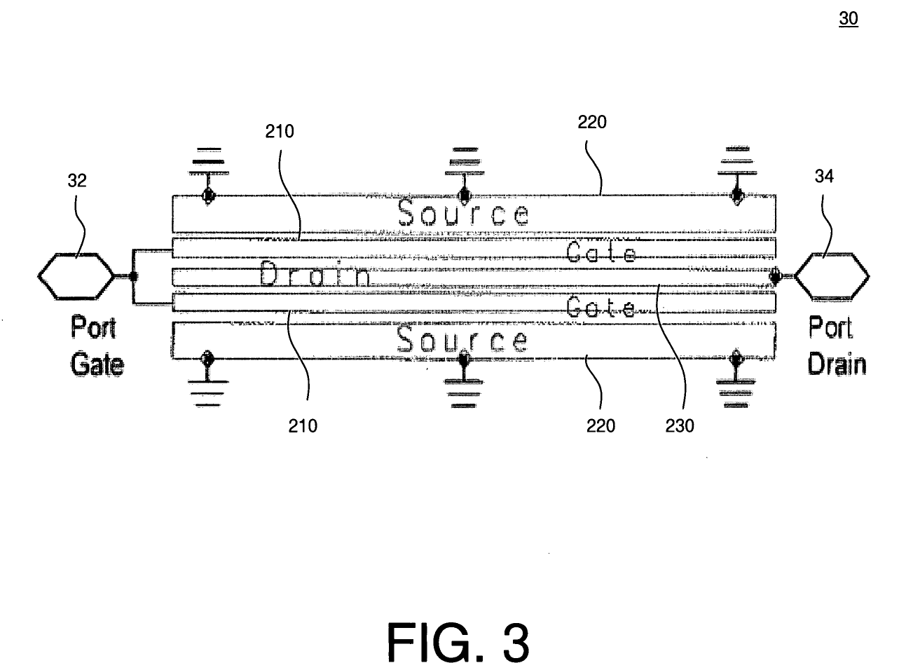

FIG. 3 shows a transistor 30 with a gate port 32 and a drain port 34 provided for connection to an external circuit. In particular, gate and drain connections to transistor 30 are provided only at a single end of each respective finger. In a typical application, an RF, microwave, or millimeter-wave input signal would be provided as an input to gate port 32, and the amplified signal would be provided as an output from drain port 34, to be supplied to an antenna or subsequent circuit. In that case, transistor 30 may be viewed as a three-terminal device with two ports. Meanwhile, however, the trace length of transistor 30 imposes undesirable parasitic effects on the external circuit in which it is employed, but it is necessary to provide the required gate periphery.

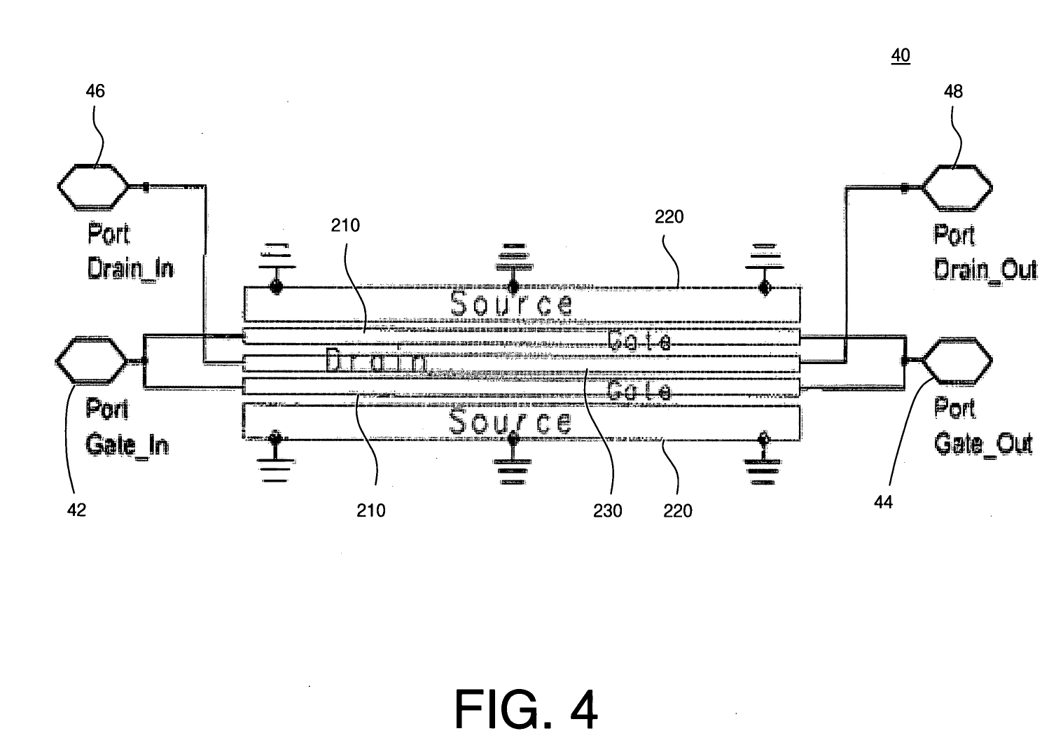

In contrast to FIG. 3, FIG. 4 shows an embodiment of a two-finger transmission line transistor 40 with five terminals and which can be operated in a circuit as a four port device. Transmission line transistor 40 is supplied with a gate input port 42, a gate output port 44, a drain input port 46, and a drain output port 48 provided for connection to external circuits. In one typical application, an RF, microwave, or millimeter-wave input signal would be provided as an input to gate input port 42, and the amplified signal would be provided as an output from drain output port 48, to be supplied to an antenna or subsequent circuit. A gate load having the same impedance as the characteristic impedance of the gate transmission line (e.g., 50 ohms) would be connected to gate output port 44. A drain load having the same impedance as the characteristic impedance of drain transmission line (e.g., 50 ohms) would be connected to drain input port 46.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. A transistor, comprising
a gate configured as a gate transmission line having a first characteristic impedance at a particular bias condition, the gate having an input at a first end thereof, and an output at a second end thereof;
a source configured as a source transmission line having a second characteristic impedance at the particular bias condition, the source having an input at a first end thereof, and an output at a second end thereof; and
a drain configured as a drain transmission line having a third characteristic impedance at the particular bias condition, the drain having an input at a first end thereof, and an output at a second end thereof.

2. The transistor of claim 1, wherein the first, second, and third characteristic impedances are all the same as each other.

3. The transistor of claim 2, wherein the first, second, and third characteristic impedances are each 50 ohms.

4. The transistor of claim 1, wherein the first characteristic impedance is different from the third characteristic impedance.

5. The transistor of claim 1, wherein the gate comprises two gate finger traces separated and spaced apart from each other, the two gate finger traces being connected to each other at the first end of the gate and at the second end of the gate.

6. The transistor of claim 5, wherein the drain is disposed between the two gate fingers.

7. The transistor of claim 5, wherein the source comprises two source finger traces separated and spaced apart from each other.

8. The transistor of claim 1, further comprising:
a gate input port terminal at the first end of the gate;
a gate output port terminal at the second end of the gate;
a drain input port terminal at the first end of the drain; and
a drain output port terminal at the second end of the drain,
wherein the first end of the gate is aligned with the first end of the drain, and the second end of the gate is aligned with the second end of the drain.

9. The transistor of claim 8, wherein the source is grounded.

10. A method of providing a transistor, comprising:
selecting a first characteristic impedance for a gate transmission line;
selecting a second characteristic impedance for a source transmission line;
selecting a third characteristic impedance for a drain transmission line;
providing a gate configured as the gate transmission line having the first characteristic impedance at a particular bias condition, the gate having an input at a first end thereof, and an output at a second end thereof;
providing a source configured as the source transmission line having the second characteristic impedance at the particular bias condition, the source having an input at a first end thereof, and an output at a second end thereof; and
providing a drain configured as the drain transmission line having the third characteristic impedance at the particular bias condition, the drain having an input at a first end thereof, and an output at a second end thereof.

11. The method of claim 10, wherein selecting the second characteristic impedance comprises selecting the second characteristic impedance to be the same as the first characteristic impedance, and wherein selecting the third characteristic impedance comprises selecting the third characteristic impedance to be the same as the first characteristic impedance.

12. The method of claim 10, wherein selecting the third characteristic impedance comprises selecting the third characteristic impedance to be the different from the first characteristic impedance.

13. The method of claim 10, wherein providing a gate comprises providing two gate finger traces separated and spaced apart from each other, the two gate finger traces being connected to each other at the first end of the gate and at the second end of the gate.

14. The method of claim 13, wherein the drain is provided between the two gate finger traces.

15. The method of claim 13, wherein providing the source comprises providing two source finger traces separated and spaced apart from each other.

16. The method of claim 10, further comprising providing a gate port terminal at the first end of the gate and a drain terminal at the second end of the drain.

17. The method of claim 10, further comprising providing a drain port terminal at the second end of the drain, wherein the first end of the gate is aligned with the first end of the drain, and the second end of the gate is aligned with the second end of the drain.

18. The method of claim 10, where the particular bias condition is at a pinch-off voltage of the transistor.
